(19) United States
(12) Patent Application Publication
(10) Pub. No.: US 2002/0038910 A1
(43) Pub. Date: Apr. 4, 2002

(54) SEMICONDUCTOR DEVICE AND METHOD OF MANUFACTURING THE SAME

(76) Inventors: TOSHIKAZU INOUE, AIZUWAKAMATSU-SHI (JP); TADASHI KINOSHITA, AIZUWAKAMATSU-SHI (JP); KAZUTOSHI MOCHIZUKI, AIZUWAKAMATSU-SHI (JP); SHUN-ICHI FUKUYAMA, KAWASAKI-SHI (JP); MORIO SHIOHARA, KAWASAKI-SHI (JP)

Correspondence Address: ARMSTRONG,WESTERMAN, HATTORI,, MCLELAND & NAUGHTON, LLP, 1725 K STREET, NW, SUITE 1000, WASHINGTON, DC, 20006, US

(21) Appl. No.: 09/473,988

(22) Filed: Dec. 29, 1999

(30) Foreign Application Priority Data
May 20, 1999 (JP) 11-140346

(51) Int. Cl. H01L 23/48; H01L 23/52; H01L 29/40

(52) U.S. Cl. 257/758

(57) ABSTRACT

The fact is utilized that a threshold at which the degassing amount will steeply change upon variations in SiH content exists in the relation between the hydrophobic SiH content of an HSQ (Hydrogen SilsesQuioxane) film and the degassing amount from the HSQ film. An HSQ film having a relative SiH content or absolute H content so as to correspond to the threshold or more is used as one insulating layer in an insulating interlayer. The hygroscopicity of the HSQ film is reduced to suppress any line defects that are considered to be generated in an upper insulating layer owing to elimination of a hygroscopic component. Satisfied are both the demand for improving the reliability of a small contact hole and the demand for suppressing any interconnection delay. The integration degree of a semiconductor device can easily and reliably be increased.

### BACKGROUND OF THE INVENTION

1. Field of the Invention

The present invention relates to a semiconductor device having an insulating interlayer including a low-permittivity insulating layer, and method of manufacturing the same and, more particularly, to a semiconductor device and a method of manufacturing the same preferably applied to a semiconductor memory and the like requiring a high integration degree.

2. Description of the Related Art

In recent years, shrinkage in feature size of mainly photolithography patterns, and improvement of the quality of insulating interlayers are being advanced to meet the demand for increasing integration degrees of semiconductor devices. In a multilevel interconnection technique for decreasing the pattern size, the formation precision of a small contact hole must be increased. For realizing a high-quality insulating interlayer, a low-permittivity insulating film must be used to suppress any interconnection delay along with an increase in integration degree.

Conventionally, an interconnection using a contact hole is made as follows. An insulating interlayer formed to cover a lower interconnection layer on a silicon substrate is anisotropically etched to form a contact hole for exposing part of the surface of the lower interconnection layer. An aluminum-based alloy is then applied to fill the contact hole, and patterned into an upper interconnection layer on the insulating interlayer. The lower and upper interconnection layers are electrically connected.

In case of miniaturizing the contact hole, however, if the contact hole is formed by anisotropic etching only, the aluminum-based alloy may become thin at the edge of the contact hole, or the interconnection layer may be disconnected by heating in a manufacturing process of the semiconductor device.

A preferable method for solving these problems is described in Japanese Patent Application Laid-Open No. 90523/1981. According to this method, isotropic etching is performed prior to anisotropic etching for forming a contact hole. More specifically, before an impurity region of a semiconductor device is exposed by anisotropic etching, the edge of the contact hole is substantially moderately tapered by isotropic etching. In this manner, the aluminum-based alloy uniformly covers the peripheral portion of the contact hole with its interior to prevent disconnection of the interconnection layers, even if the contact hole is very small.

Suitable examples of the low-permittivity insulating film material for suppressing an interconnection delay are so-called SOG (Spin On Glass) and HSQ (Hydrogen SilsesQuioxane). SOG can form a coating film excellent in flatness, low in permittivity, but poor in adhesion properties with aluminum or an aluminum-based alloy used as an interconnection material. SOG may cause voids beside the interconnection after forming an insulating film. When the insulating layer is humidified, water may stay beside the interconnection to corrode and damage the interconnection material. In comparison with this, HSQ is low in permittivity, can be easily formed, and is excellent in flatness and adhesion properties with interconnection materials. So, HSQ is one of the most suitable insulating film materials for increasing integration degrees of semiconductor devices.

But, in case of isotropic etching particularly for forming a contact hole by using wet etching according to the method described in the Japanese Patent Application Laid-Open No. 90523/1981, an HSQ film formed as an insulating layer in an insulating interlayer causes the following serious problems.

Since such an HSQ film has a relatively high water content, a CVD (Chemical Vapor Deposition) insulating layer is often formed to cover the HSQ film in order to seal water vapor produced from the HSQ film in a heating step in a manufacturing process.

In this case, water vapor produced from the HSQ film can be sealed by the CVD insulating layer, but the CVD insulating layer becomes easy to get line defects owing to the water vapor. The above method performs isotropic etching using an etchant to a portion of the CVD insulating layer serving as the edge of a contact hole. If the CVD insulating layer has line defects, the etchant erodes the underlying HSQ film through the line defects. Since the HSQ film has a higher etching rate than the CVD insulating layer, the HSQ film is greatly damaged by the eroding etchant. This causes serious etching defects.

More specifically, if satisfactory isotropic etching is done so as reliably to prevent disconnection of an aluminum-based alloy in a formation of an interconnection layer, etching defects increases in the HSQ film accordingly. If the isotropic etching amount is reduced, etching defects can be suppressed but the aluminum-based alloy is easily disconnected. As the integration degree of a semiconductor device increases, contradictory demands, i.e., the demand for improving the reliability of a small contact hole and the demand for suppressing the interconnection delay must be adjusted. This makes it more difficult to realize a high integration degree.

### SUMMARY OF THE INVENTION

It is an object of the present invention to provide an insulating film with a contact hole, and a formation method thereof capable of satisfying both the demand for improving the reliability of a small contact hole and the demand for suppressing any interconnection delay, and capable of easily and reliably increasing integration degrees of various devices, in particular, semiconductor devices, and to provide a semiconductor device having such an insulating film, and a method of manufacturing the same.

To achieve the above object, the present invention has the following aspects.

According to the first aspect, the present invention is directed to an insulating film formed on a conductive film and including an insulating layer of a composition containing SiH, and a formation method thereof. According to this first aspect, the insulating layer has an H content of not less than 15.4 atom % in the composition.

According to the second aspect, the present invention is directed to an insulating interlayer and a formation method thereof, like the first aspect. According to this second aspect, the insulating layer has an SiH content at which a degassing amount from the insulating layer abruptly decreases upon a slight increase in the SiH content.

According to the third aspect, the present invention is directed to a formation method of an insulating interlayer, like the first aspect. The formation method comprises steps of applying a material film for the insulating layer, and curing the material film with adjusting an SiH content in the material film to a predetermined value of not less than 50% an SiH content immediately after applying.

The present invention according to the first to third aspects can apply to a semiconductor device comprising an insulating interlayer which is formed on a conductive film and includes an insulating layer of a composition containing SiH, and a manufacturing method thereof. In this case, the present invention applies in particular to a semiconductor device in which a contact hole is formed to expose part of a surface of the conductive film, an interconnection layer is formed so as to be electrically connected to the conductive film through the contact hole, and the contact hole has an upper wall surface moderately tapered. The constituent element formed under the insulating interlayer may be a semiconductor element formed on a semiconductor substrate, or a multilayered interconnection structure, in place of the conductive film.

The present invention according to the first to third aspects can also apply to a formation method of a contact hole. According to this formation method, an insulating layer of a composition containing SiH is formed by any formation method according to the first to third aspects, an upper insulating layer is then formed thereon, a surface layer of the upper insulating layer is then isotropically etched to form a recess having a moderately tapered wall surface on the surface layer, and then a contact hole is formed so as to extend from the recess through the insulating interlayer and to expose part of a surface of the conductive film.

The present inventors have found that a threshold at which the degassing amount will steeply change upon variations in SiH content exists in the relation between the hydrophobic SiH content of an HSQ film and the degassing amount from the HSQ film (see FIG. 7). In other words, the degassing amount abruptly decreases upon a slight increase in the SiH content at the boundary of this threshold.

In forming an insulating interlayer including the HSQ film, the threshold corresponds to an SiH content of 50% in the HSQ film after curing with respect to the SiH content of the HSQ film immediately after coating. The HSQ composition is given by HSiO_{1.5}. Two H atoms are eliminated and one O atom is introduced by curing crosslinking reaction. For an SiH content of 50%, the HSQ composition is given by H_{0.5}SiO_{1.75}. The H content of the HSQ film at this time is (0.5/3.25)×100≈15.4 atom %. From this, “the SiH content of the HSQ film after curing with respect to the SiH content of the HSQ film immediately after coating is 50% or more” is equivalent to the feature that the absolute value of the H content of the HSQ film is 15.4 atom % or more. If the H content (atom %) is defined in this way, the composition state of the HSQ film corresponding to the threshold can be defined not by relative comparison values of various states during formation of the HSQ film, but uniquely for the finally formed HSQ film.

The present invention utilizes the above property of the HSQ film. The HSQ film having a relative SiH content or absolute H content so as to correspond to the threshold or more is used as one insulating layer in the insulating interlayer. The hygroscopicity of the HSQ film is greatly reduced to suppress any line defects that are considered to be generated in an upper insulating layer (e.g., CVD insulating layer) owing to elimination of a hygroscopic component.

Hence, even if the upper insulating layer is satisfactorily isotropically etched to prevent disconnection of an applied interconnection material in forming a small contact hole in the insulating interlayer, no line defect is generated in the CVD insulating layer, and no etchant erodes into the lower insulating layer (HSQ film). That is, since the insulating interlayer is used between, e.g., interconnection layers of a multilayered semiconductor device, any interconnection delay can be suppressed, and the interconnection layers can be easily and accurately connected.

The present invention employs, as an insulating interlayer, the insulating layer using a low-permittivity insulating material suitable for suppressing the interconnection delay, and can realize a reliable multilayered interconnection using a small contact hole. That is, the present invention can meet both the demand for improving the reliability of a small contact hole and the demand for suppressing any interconnection delay, and can increase integration degrees of various devices, in particular, semiconductor devices.

### BRIEF DESCRIPTION OF THE DRAWINGS

FIGS. 1A to 1H are schematic sectional views respectively showing steps for forming a contact hole in an insulating interlayer to form a multilevel interconnection according to the first embodiment of the present invention;

FIG. 2 is a graph showing the sequence of a curing step subsequent to a baking step in forming an HSQ film;

FIG. 3 is a schematic sectional view showing an HSQ film formed without controlling its SiH content;

FIGS. 4A and 4B are schematic sectional views respectively showing a comparative example in which an HSQ film is formed without controlling its SiH content and a single-layered oxide film is formed to cover the HSQ film;

FIG. 5 is a graph showing a relation between the SiH content of an HSQ film and the degassing amount from the HSQ film;

FIG. 6 is a graph showing a result of measuring the relative value of the spectrum of an HSQ film by a Fourier transformation infrared spectrophotometry (FT-IR);

FIG. 7 is a graph showing a relation between an isotropic etching amount and the number of bubble defects;

FIGS. 8A to 8C are graphs respectively showing relations between SiH contents (%) and the load-in temperature, load-out temperature, and holding time after load-in when an HSQ film is cured; and

FIG. 9 is a schematic sectional view showing the main part of a flash memory according to the second embodiment of the present invention.

### DETAILED DESCRIPTION OF THE PREFERRED EMBODIMENTS

Preferred embodiments of the present invention will be described below in detail with reference to the accompanying drawings.

### First Embodiment

The first embodiment of the present invention will exemplify a semiconductor device to which the present invention is applied. The structure of the semiconductor device will be described along with a method suitable for realizing a multilevel interconnection by forming a small contact hole for interconnection in an insulating interlayer.

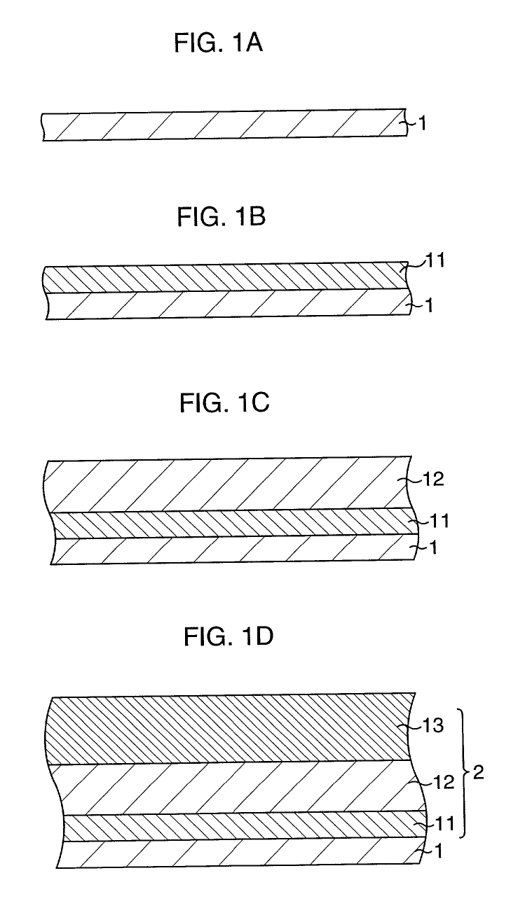

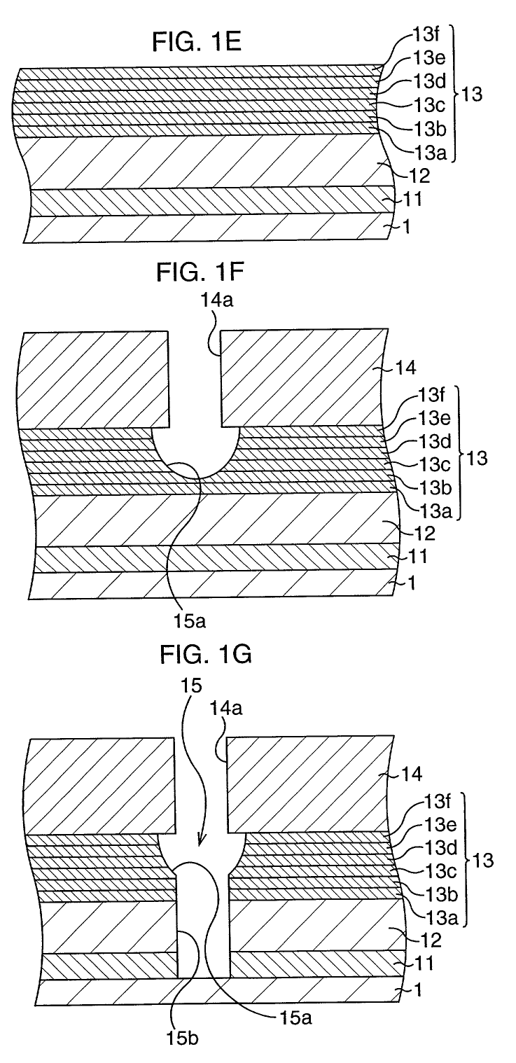

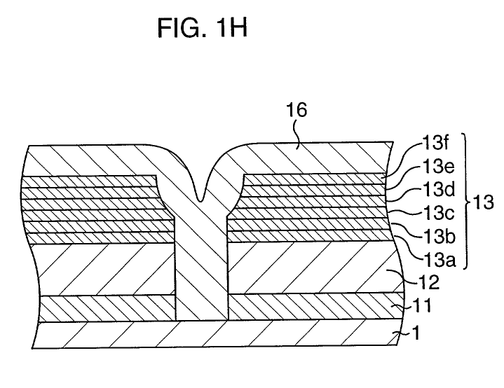

FIGS. 1A to 1H are schematic sectional views respectively showing steps for forming a contact hole in an insulating interlayer to form a multilevel interconnection.

As shown in FIG. 1A, an aluminum-based alloy is sputtered onto a semiconductor substrate having various semiconductor elements on its surface (neither of them are shown), and patterned into a conductive film 1 serving as a lower interconnection layer.

To cover the conductive film 1, a three-layered insulating interlayer 2 as the main feature of the first embodiment is formed. The insulating interlayer 2 is formed by sequentially stacking a CVD silicon oxynitride film 11 (to be simply referred to as oxynitride film 11), an HSQ (Hydrogen SilsesQuioxane) film 12, and a CVD silicon oxide film 13 (to be simply referred to as oxide film 13).

More specifically, the oxynitride film 11 is deposited by plasma CVD to cover the conductive film 1, as shown in FIG. 1B.

Then, as shown in FIG. 1C, the HSQ film 12 as a low-permittivity insulating layer for suppressing any interconnection delay is formed on the oxynitride film 11. Since this HSQ film 12 is formed by coating, it can easily attain desired flatness. The HSQ film 12 undergoes baking as pre-processing and curing as main processing. For the following reason, the SiH content of the HSQ film 12 after curing is adjusted to a predetermined content equal to or more than 50% the SiH content immediately after coating.

In the baking step, the HSQ film 12 is baked three times. First, the HSQ film 12 is baked at 150° C. for 1 min in order to eliminate a volatile solvent component in the HSQ film 12. Then, the HSQ film 12 is baked at 200° C. for 1 min in order to reflow the HSQ film 12. Finally, the HSQ film 12 is baked at 350° C. for 1 min in order to solidify the HSQ film 12.

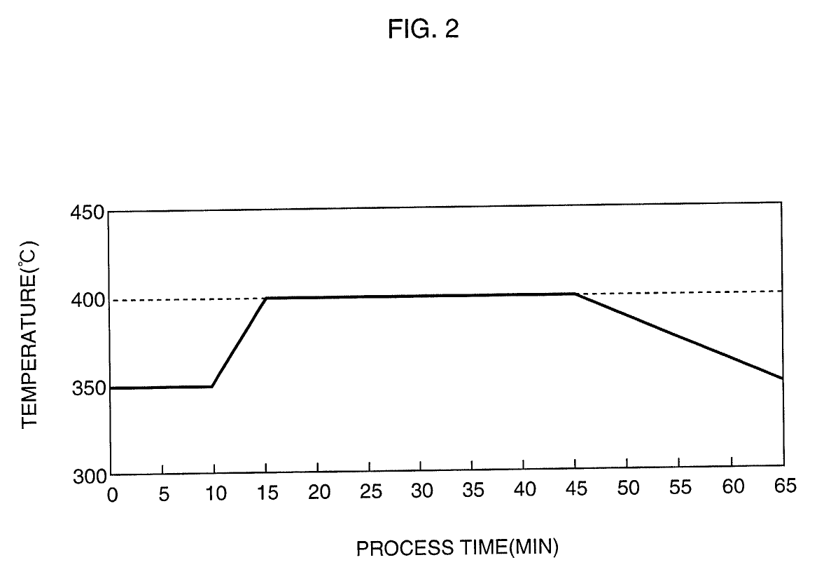

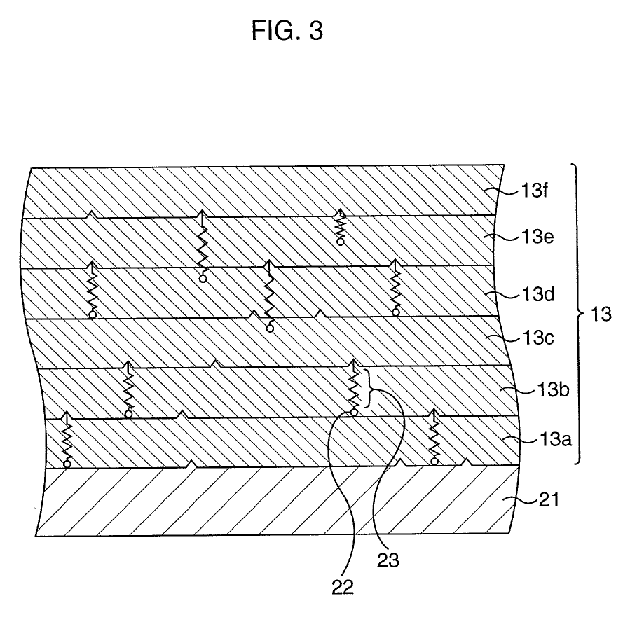

FIG. 2 shows the sequence of the curing step subsequent to the baking step. As indicated with a solid line in FIG. 2, N₂ gas is introduced into a predetermined curing oven at a flow rate of 30 SL, and a semiconductor substrate is loaded therein at 350° C. and held at the same temperature for 10 min. The semiconductor substrate is then cured at 400° C. for 30 min. After curing, the semiconductor substrate is decreased in temperature to 350° C. and loaded out.

By defining the holding time after load-in, the residual oxygen amount in the curing oven can be suppressed. This can control crosslinking reaction between HSQ and oxygen to adjust the SiH content left in the HSQ film 12 to a predetermined content as described above.

As shown in FIG. 1D, the oxide film 13 is deposited on the HSQ film 12 by plasma CVD. Since HSQ is an insulating material having a relatively high water content, the oxide film 13 is formed to cover the HSQ film 12 in order to seal water vapor produced from the HSQ film 12 in a heating step in the manufacture. That is, the HSQ film 12 is covered from above and below the oxide film 13 and oxynitride film 11 to prevent diffusion of the water vapor.

In this case, as shown in FIG. 1E, the oxide film 13 may be formed into a multilayered, e.g., six-layered (oxide layers 13a to 13f) structure in order more reliably to suppress line defects apt to be generated in the upper CVD oxide film owing to water vapor from the HSQ film, which is one of the main objects of the present invention. For descriptive convenience, the oxide film 13 has such a six-layered structure.

The oxide layers 13a to 13f are sequentially formed at thicknesses of 65 nm, 65 nm, 80 nm, 80 nm, 80 nm, and 80 nm, respectively, so that the oxide film 13 has a thickness of about 450 nm. The multilayered oxide film 13 is formed thus. Consequently, even if many line defects 23 have been developed from defective nuclei 22 as a result of forming an HSQ film 21 without controlling its SiH content unlike the first embodiment, the line defects 23 do not expand or extend, and can be suppressed short within the respective layers 13a to 13f, as shown in FIG. 3 that is an enlarged view showing the oxide film 13. When the multilayered oxide film 13 is formed by controlling the SiH content like the first embodiment, generation of line defects can be suppressed.

After the oxide film 13 is formed, a photoresist 14 is applied to the surface of the oxide film 13, and formed into a contact pattern 14a by photolithography, as shown in FIG. 1F.

An etchant is applied through the contact pattern 14a to the oxide film 13 exposing through the contact pattern 14a, and the oxide film 13 is isotropically etched by about 300 nm. In this case, the etchant has a ratio (water:HF:NH₄F) of (130:1:7), (94.4:1:8.65), or (40:1:0). This isotropic etching forms a moderately tapered wide recess 15a around the contact pattern 14a being almost at the center of the oxide film 13 below the photoresist 14.

As shown in FIG. 1G, an opening 15b conforming to the contact pattern 14a is formed in the oxide film 13, HSQ film 12, and oxynitride film 11 by anisotropic etching, e.g., general RIE (Reactive Ion Etching) using the photoresist 14 as a mask. This opening 15b exposes part of the surface of the conductive film 1. As a result, a contact hole 15 made up of the recess 15a and opening 15b is formed. An example of the etching gas used in RIE is Freon-based gas such as a gas mixture of CHF₃ and CF₄. The flow rates of gas components are adjusted to 70 sccm for CHF₃, 60 sccm for CF₄, 417 sccm for Ar, 1,042 sccm for He, and 30 sccm for N₂, respectively. The RF application power and pressure are set to 1,400 W and 1,000 Torr, respectively.

The photoresist 14 is removed by ashing or the like, and then a native oxide film (not shown) formed on the surface of the conductive film 1 exposed through the contact hole 15 is removed. This native oxide film is formed in contact with air when the substrate is conveyed to a sputtering chamber in order to sputter the following aluminum-based alloy. If the substrate does not pass through air even during the conveyance, no native oxide film is formed. In this case, the removal step for such a native oxide film can be omitted.

As shown in FIG. 1H, an aluminum-based alloy is sputtered on the surface of the oxide film 13 so as to fill the contact hole 15. Examples of the aluminum-based alloy are aluminum—1% silicon, aluminum—0.5% silicon—0.5% copper, and aluminum—0.5% silicon—0.5% titanium in consideration of prevention of migration, generation of alloy spikes on the substrate, and the like. In this case, although the contact hole 15 is very small, the contact hole 15 is wide at its upper portion (recess 15a), and the wall surface of the hole (wall surface of the recess 15a) has a moderate slope. So, the aluminum-based alloy is substantially uniformly applied to this portion to relax or cancel a so-called shadowing effect of sputtering. The contact hole 15 is therefore surely filled with the aluminum-based alloy without disconnection around the hole, and the aluminum-based alloy is spread on the oxide film 13 with an almost uniform thickness.

After this, the aluminum-based alloy on the oxide film 13 is patterned by photolithography and subsequent dry etching to form an interconnection layer (upper interconnection layer) 16 that extends on the oxide film 13 and is electrically connected to the underlying conductive film 1 through the contact hole 15.

As described above, the first embodiment forms the HSQ film 12 as an insulating layer in the insulating interlayer 2. This HSQ film 12 is a coating film excellent in flatness, and is a low-permittivity insulating layer for suppressing any interconnection delay that is apt to occur along with an increase in integration degree of the semiconductor device. The SiH content (or H content) of the HSQ film 12 is adjusted to a predetermined value as described below.

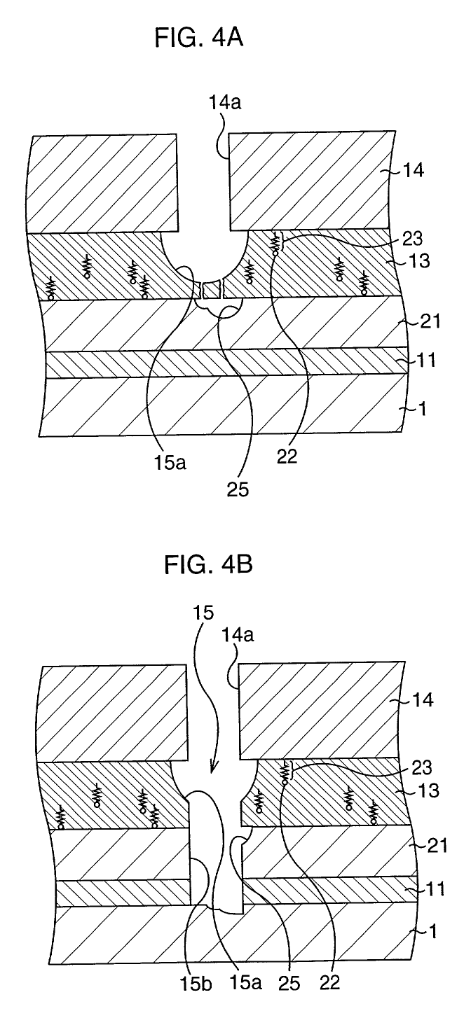

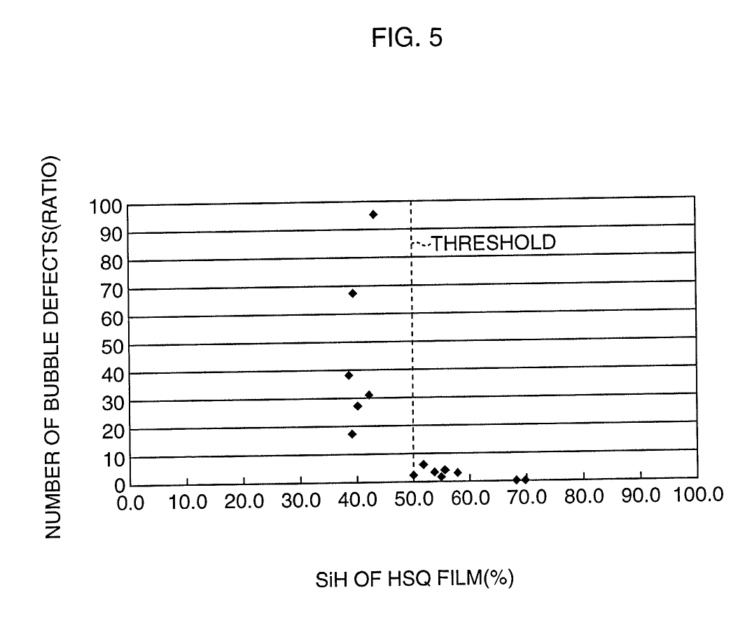

Since HSQ is an insulating material having a relatively high water content, a CVD insulating layer (e.g., oxide film 13) for covering the HSQ film is formed to seal water vapor produced from the HSQ film in a heating step in the manufacture. FIGS. 4A and 4B show a comparative example in which an HSQ film 21 is formed without controlling its SiH content and a single-layered oxide film 13 is formed to cover the HSQ film 21. FIG. 4A shows the step of forming a recess 15a by isotropic etching at the upper portion of a portion to be a contact hole 15, like the first embodiment. FIG. 4B shows the step of forming the contact hole 15. In this comparative example, long line defects 23 are developed from defective nuclei 22 in the oxide film 13 owing to water vapor produced from the HSQ film 21 during a heating step in forming the oxide film 13. If the surface layer of the oxide film 13 is isotropically etched in this state to form a recess 15a enough to relax or cancel the shadowing effect, the etchant erodes the HSQ film 21 through the line defects 23 to generate a so-called bubble defect 25 as a hollow etching defect. This greatly degrades the product reliability.

To prevent this, the present inventors have found that generation of line defects in such an overlying CVD insulating layer (oxide film 13) can be suppressed by adjusting the hydrophobic SiH content (or H content) so as to control the high water content of HSQ. To implement this idea, a relation between the SiH content of a HSQ film and the degassing amount from the HSQ film was examined and found that the degassing amount has a threshold at which the degassing amount changes steeply upon variations in SiH content.

FIG. 5 shows a detailed measurement result, in which the degassing amount is defined by the number of bubble defects caused thereby, and measured by observing the number of bubble defects on a subscribed line of a substrate.

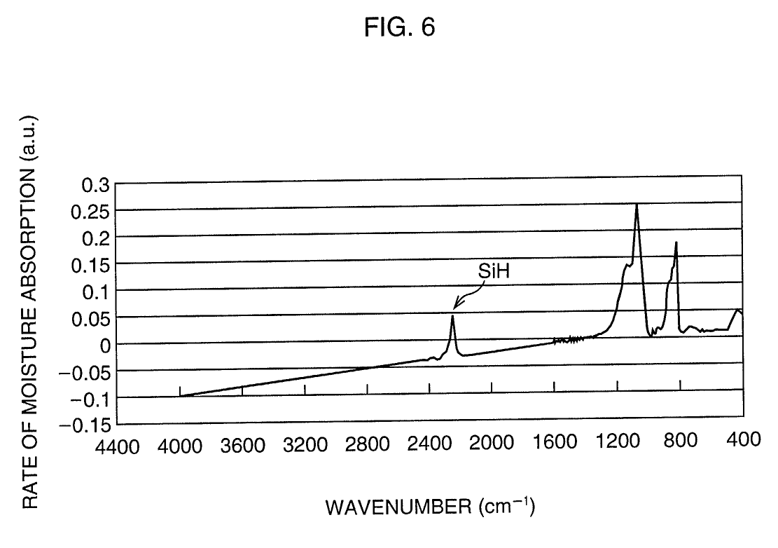

The SiH content in the HSQ film is defined by the ratio (%) of the SiH content after curing to the SiH content immediately after coating. The SiH content in each state was obtained by measuring the relative value of the spectrum of the HSQ film by a Fourier transformation infrared spectrophotometry (FT-IR). FIG. 6 shows a spectrum measurement result. In FIG. 6, the peak appearing at a wavenumber around 2,250 (1/cm) represents absorption by Si—H bonds in the HSQ film. By defining the peak intensity immediately after coating as 100%, the SiH content left after curing was evaluated.

As shown in FIG. 5, the number of bubble defects abruptly decreases at an SiH content around 50%. The threshold at which the number of bubble defects abruptly decreases, exists around this SiH content. This phenomenon suggests that the hydroscopicity of the HSQ film was suppressed by an increase in residual SiH content, degassing to the overlying CVD insulating layer was suppressed, and thus generation of line defects in the CVD insulating layer was suppressed, and thereby the number of bubble defects decreased greatly.

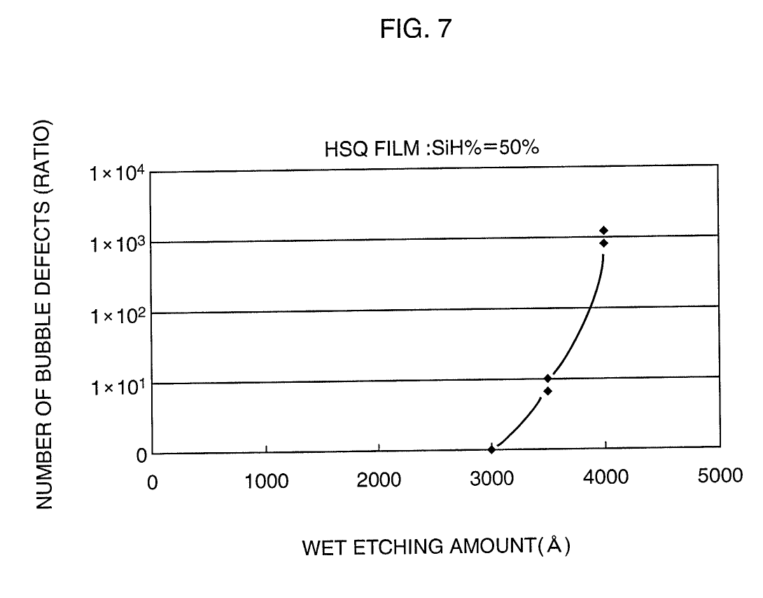

Further, the present inventors examined a relation between an etching amount and the number of bubble defects by controlling the SiH content left in a HSQ film 12 to 50%. FIG. 7 shows the measurement result. An etching amount enough to relax or cancel a so-called shadowing effect has been considered to be about 3,000 Å. As shown in FIG. 7, when the etching amount is 3,000 Å, the number of bubble defects is suppressed to almost 0. Consequently, it is found that a sufficient isotropic etching amount can be ensured when the SiH content is controlled to 50%.

Note that the relation between the SiH content (%) and the number of bubble defects may change depending on variations in material and manufacturing conditions. Even in such a case, a threshold as described above exists that has slightly shifted with respect to the SiH content. To cope with this, for example, the curing conditions of the HSQ film are made to match the variations so as to adjust the SiH content equal to or more than the shifted threshold.

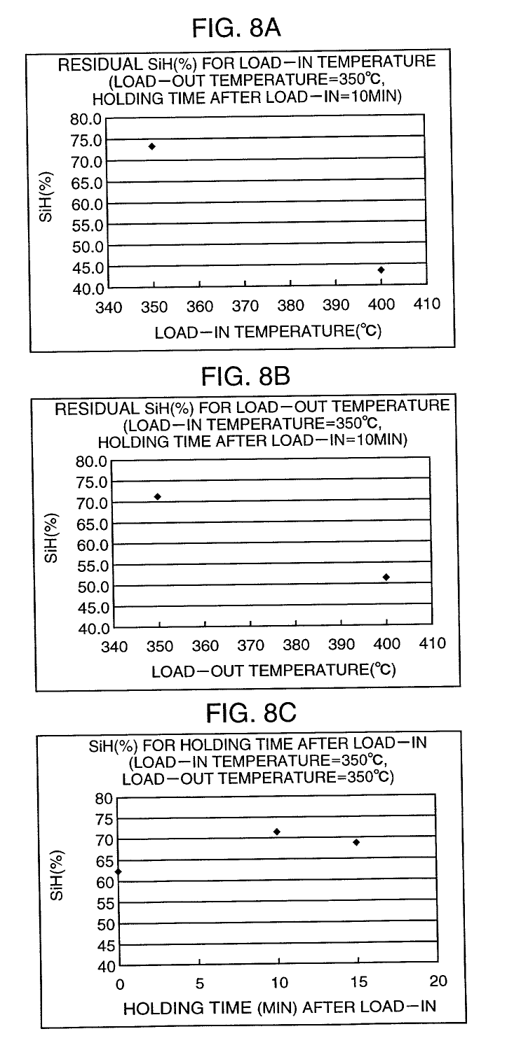

The SiH content left in the HSQ film 12 should be controlled in consideration of the load-in temperature, subsequent holding time, and load-out temperature in curing the HSQ film 12, as described in this embodiment. FIGS. 8A to 8C show relations between these conditions and SiH content (%). FIG. 8A shows a relation between the load-in temperature and SiH content, FIG. 8B shows a relation between the load-out temperature and SiH content, and FIG. 8C shows a relation between the holding time after load-in and SiH content. In FIG. 8A, the load-out temperature and holding time after load-in are 350° C. and 10 min, respectively. In FIG. 8B, the load-in temperature and holding time after load-in are 350° C. and 10 min, respectively. In FIG. 8C, the load-in and load-out temperatures are 350° C. each.

These results suggests that the SiH content left in the HSQ film 12 can be adjusted to a satisfactory value, in this case to 70% or more, when the load-in and load-out temperatures and the holding time after load-in are controlled to 350° C. and 10 min, respectively. It was confirmed that reaction to residual oxygen is suppressed by setting the load-in time as relatively low as 350° C., and the residual oxygen density is reduced by setting the holding time after load-in to 10 min. By controlling these conditions, crosslinking reaction that Si—H changes to Si—O—Si can be adjusted to obtain a high residual SiH content.

In this fashion, the first embodiment forms the HSQ film 12 such that the ratio of the SiH content of the HSQ film 12 after curing to the SiH content immediately after coating is adjusted to a predetermined value equal to or more than 50%. This can greatly reduce the hygroscopicity of the HSQ film 12 to suppress any line defects which are considered to be generated in the oxide film 13 as an overlying insulating layer owing to elimination of a hygroscopic component.

Even when the oxide film 13 is satisfactorily isotropically etched in forming the contact hole 15 in the HSQ film 12 in order to prevent disconnection of an applied interconnection material, no line defect is generated in the oxide film 13, and no etchant erodes into the underlying HSQ film 12. That is, since the insulating interlayer 2 is used between, e.g., interconnection layers of a multilayered semiconductor device, more excellent flatness can be achieved to suppress any interconnection delay, and the interconnection layers can be easily and accurately connected.

The HSQ composition is given by HSiO_{1.5}. Two H atoms are eliminated and one O atom is introduced by curing crosslinking reaction. So, when the SiH content is 50%, the HSQ composition is given by H_{0.5}SiO_{1.75}. The H content of the HSQ film at this time is (0.5/3.25)×100≈15.4 atom %. From this, “the ratio of the SiH content of the HSQ film after curing to the SiH content of the HSQ film 12 immediately after coating is 50% or more” is equivalent to the feature that the absolute value of the H content of the HSQ film 12 is 15.4 atom % or more. If the H content (atom %) is defined in this way, the composition state of the HSQ film 12 corresponding to the threshold can be defined not with relative comparison values of various states during formation of the HSQ film 12, but uniquely for the finally formed HSQ film 12.

### Second Embodiment

The second embodiment of the present invention will exemplify a flash memory as a semiconductor memory using such an insulating interlayer as described in the first embodiment. Note that the same reference numerals as in the first embodiment denote the same parts as in the first embodiment.

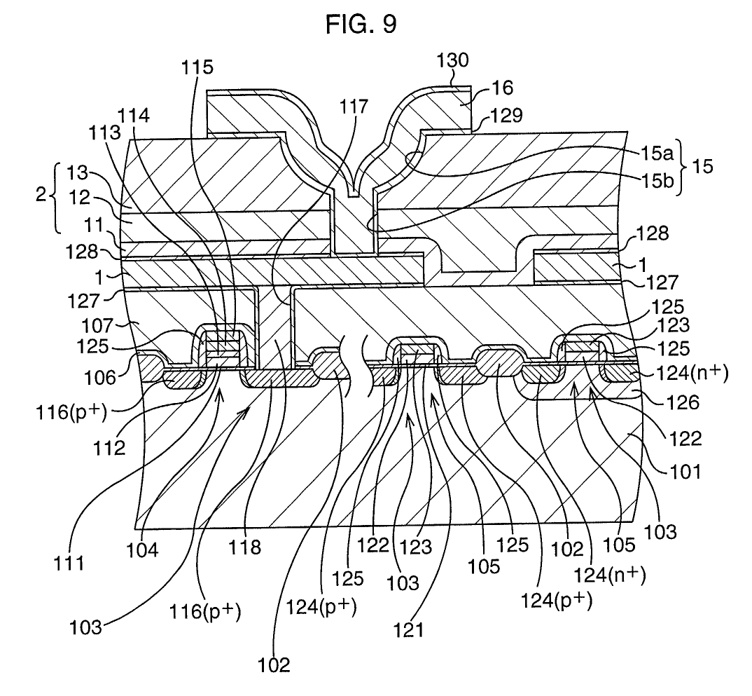

FIG. 9 is a schematic sectional view showing the main part of the flash memory according to the second embodiment.

In this flash memory, element isolation structures 102 are formed on an n-type semiconductor substrate 101 by, e.g., a LOCOS method to define element activation regions 103. Memory cells 104 are formed in element activation regions 103 forming memory cell regions, and MOS transistors 105 are formed in element activation regions 103 forming peripheral circuit regions. A plasma CVD oxide film 106 and an insulating interlayer 107 (made of a material such as PSG, BPSG, or high-density plasma oxide) are formed to cover the memory cells 104 and MOS transistors 105. A conductive film 1 is patterned on the insulating interlayer 107. A three-layered insulating interlayer 2 is formed to cover the conductive film 1. Further, an interconnection layer 16 is patterned to fill a small contact hole 15 formed in the insulating interlayer 2 and to extend on the insulating interlayer 2. The conductive film 1 and interconnection layer 16 are electrically connected through the contact hole 15.

Each memory cell 104 is formed as follows. An island-like floating gate 112 made of a polysilicon film is formed on a tunnel insulating film 111 formed on the surface of the semiconductor substrate 101. A control gate 114 and a cap insulating film 115 extending like a band are formed on a dielectric film 113 on the floating gate 112. Source and drain regions 116 (each of which will be referred to as source/drain 116 hereinafter) are formed in the surface regions of the semiconductor substrate 101 on both sides of the control gate 114 by implanting impurity ions. A contact hole 117 is formed in the insulating interlayer 107 so as to expose part of the surface of the source/drain 116. The contact hole 117 is filled with a tungsten plug 118. The source/drain 116 and conductive film 1 are electrically connected through the tungsten plug 118.

The memory cell 104 functions as a capacitor formed by sandwiching the dielectric film 113 between the floating gate 112 and control gate 114, and executes, e.g., the following memory information write and erase.

Memory information is written by applying a predetermined voltage to the control gate 114 to accumulate hot electrons, which have been produced near the drain 116, within the floating gate 112. Memory information is erased by using an FN (Fowler-Nordheim) current that flows between the source 116 and floating gate 112 when the control gate 114 is grounded and a high voltage is applied to the source 116.

Each MOS transistor 105 is formed as follows. A band-like gate electrode 122 and a cap insulating film 123 formed on the electrode 122 are patterned on a gate insulating film 121 formed on the surface of the semiconductor substrate 101. Impurity ions are implanted into the semiconductor substrate 101 on both sides of the gate insulating film 121 to form source and drain regions 124. Like the source/drain 116, the source/drain 124 is electrically connected to the overlying conductive film 1 through a contact hole (not shown) formed in the insulating interlayer 107.

Sidewall insulators (sidewalls) 125 for covering both side surfaces of the structure of the floating gate 112, dielectric film 113, and control gate 114, and both side surfaces of the structure of the gate electrode 122 and cap insulating film 123 may be formed commonly to the memory cell 104 and MOS transistor 105. And, before and after the sidewalls 125 are formed, ion implantation may be performed twice so as to form the source and drain regions 116 or 124 each having a so-called LDD structure. In many cases, the channel of a MOS transistor 105 is formed of n type and the channel of another MOS transistor 105 is formed of p type to constitute a CMOS inverter functioning as a peripheral circuit of the memory cells 104. In this case, as shown in FIG. 9, the MOS transistor 105 having an n-type channel may be formed by forming a p-well 126 in the semiconductor substrate 101 and forming n-type source and drain regions 124 in the p-well 126.

The conductive film 1 is patterned into an interconnection shape to function as a lower interconnection layer. This conductive film 1 is made of an aluminum-based alloy. A barrier metal layer 127 for improving adhesion properties and an antireflection film 128 for preventing light reflection in photolithography are formed below and above the conductive film 1, respectively. The barrier metal layer 127 covers the inner wall of the contact hole 117 and is in contact with the source/drain 116. That is, after the barrier metal layer 127, conductive film 1, and antireflection film 128 are stacked in this order, they are patterned into an interconnection shape.

As described in the first embodiment, the insulating interlayer 2 is obtained by sequentially stacking an oxynitride film 11, an HSQ film 12, and an oxide film 13. The HSQ film 12 is formed such that the ratio of the SiH content after curing to the SiH content immediately after coating is 50% or more, or the absolute value of the H content is 15.4 atom % or more.

An interconnection layer 16 functions as an upper interconnection layer. As described in the first embodiment, the interconnection layer 16 is connected to the conductive film 1 serving as a lower interconnection layer through a contact hole 15 having a moderately tapered wide recess 15a formed at the upper portion of the insulating interlayer 2. Also in this case, after a barrier metal layer 129, the interconnection layer 16, and an antireflection film 130 are stacked in this order, they are patterned into an interconnection shape.

In the flash memory according to the second embodiment, the HSQ film 12 whose SiH content (%) or H content (atom %) is adjusted to a predetermined value is formed as an insulating layer in the insulating interlayer 2. In addition, the gentle recess 15a is formed by isotropic etching at the upper portion of the contact hole 15. This flash memory meets both the demand for improving the reliability of the small contact hole 15 and the demand for suppressing any interconnection delay. The flash memory can easily and reliably realize a higher integration degree of the semiconductor memory.

Note that the second embodiment has exemplified the flash memory as a semiconductor memory, but the present invention is not limited to this. For example, the present invention can apply to various semiconductor devices requiring high integration degrees, e.g., various nonvolatile memories such as an EPROM and an EEPROM, volatile memories such as a DRAM, general MOS transistors, and CMOS inverters.

The present invention can suitably apply to image forming apparatus such as various display panels. For example, when thin film transistors (TFTs) are directly formed on a marginal portion of a glass substrate on which display elements for a liquid crystal display (LCD) are formed, the present invention can apply to an insulating interlayer or the like in forming the multilayered interconnection structure for the TFTs. This can realize an ideal LCD having the small TFTs which can operate at a high speed.

What is claimed is:

1. A semiconductor device comprising an insulating interlayer formed on a conductive film and including an insulating layer of a composition containing SiH,
wherein said insulating layer has an H content of not less than 15.4 atom % in the composition.

2. A semiconductor device comprising an insulating interlayer formed on a conductive film and including an insulating layer of a composition containing SiH,
wherein said insulating layer has an SiH content at which a degassing amount from said insulating layer abruptly decreases upon a slight change in the SiH content.

3. A device according to claim 1, wherein a contact hole for exposing part of a surface of said conductive film is formed, an interconnection layer electrically connected to said conductive film through said contact hole is formed, and said contact hole has a moderately tapered upper wall surface.

4. A device according to claim 2, wherein a semiconductor element is provided on a semiconductor substrate, and said conductive film is formed over said semiconductor element and electrically connected to said semiconductor element.

5. A device according to claim 1, wherein a semiconductor element is provided on a semiconductor substrate, and said conductive film is formed over said semiconductor element and electrically connected to said semiconductor element.

6. A device according to claim 5, wherein said semiconductor element comprises a memory cell having an island-like floating gate formed on a tunnel insulating film on said semiconductor substrate, a control gate extending on a dielectric film on said floating gate, and a source and a drain formed in surface regions of said semiconductor substrate on both sides of said control gate, and
memory information is written and erased by controlling the amount of electrons in said floating gate.

7. A semiconductor device comprising a semiconductor element formed on a semiconductor substrate, and a multilayered interconnection structure formed over semiconductor element and electrically connected to said semiconductor element,
wherein said multilayered interconnection structure is an interconnection structure of at least two layers in which a conductive film or a lower interconnection layer and an upper interconnection layer formed on an insulating interlayer are electrically connected through a contact hole formed in said insulating interlayer,
said insulating interlayer includes an insulating layer of a composition containing SiH, and
said insulating layer has an SiH content at which a degassing amount from said insulating layer abruptly decreases upon a slight increase in the SiH content.

8. A semiconductor device comprising a semiconductor element formed on a semiconductor substrate, and a multilayered interconnection structure formed over semiconductor element and electrically connected to said semiconductor element,
wherein said multilayered interconnection structure is an interconnection structure of at least two layers in which a conductive film or a lower interconnection layer and an upper interconnection layer formed on an insulating interlayer are electrically connected through a contact hole formed in said insulating interlayer,
said insulating interlayer includes an insulating layer of a composition containing SiH, and
said insulating layer has an H content of not less than 15.4 atom % in the composition.

9. An insulating film formed on a conductive film and including an insulating layer of a composition containing SiH,
said insulating layer having an SiH content at which a degassing amount from said insulating layer abruptly decreases upon a slight increase in the SiH content.

10. An insulating film formed on a conductive film and including an insulating layer of a composition containing SiH,
said insulating layer having an H content of not less than 15.4 atom % in the composition.

11. An insulating film formation method for an insulating interlayer to be formed on a conductive film and include an insulating layer of a composition containing SiH,
wherein said insulating layer is formed with adjusting its SiH content so that a degassing amount from said insulating layer abruptly decreases upon a slight increase in the SiH content.

12. An insulating film formation method for an insulating interlayer to be formed on a conductive film and include an insulating layer of a composition containing SiH, comprising the steps of:
applying a material film for said insulating layer; and
curing said material film with adjusting an SiH content in said material film to a predetermined value of not less than 50% an SiH content immediately after applying.

13. An insulating film formation method for an insulating interlayer to be formed on a conductive film and include an insulating layer of a composition containing SiH, comprising the steps of:
applying a material film for said insulating layer; and
curing said material film with adjusting an H content in the composition of said material film to a predetermined value of not less than 15.4 atom %.

14. A contact hole formation method, comprising the steps of:
in forming on a conductive film an insulating interlayer including an insulating layer of a composition containing SiH, forming said insulating layer with adjusting its SiH content so that a degassing amount from the insulating layer abruptly decreases upon a slight increase in the SiH content;
isotropically etching a surface layer of an upper insulating layer to form a recess having a moderately tapered wall surface on said surface layer; and
forming a contact hole which extends from said recess through said insulating interlayer to expose part of a surface of said conductive film.

15. A contact hole formation method, comprising the steps of:
in forming on a conductive film an insulating interlayer including an insulating layer of a composition containing SiH, forming said insulating layer by applying a material film for said insulating layer, and then curing said material film with adjusting an SiH content of said material film to a predetermined value of not less than 50% an SiH content immediately after applying;
isotropically etching a surface layer of an upper insulating layer to form a recess having a moderately tapered wall surface on said surface layer; and
forming a contact hole which extends from said recess through said insulating interlayer to expose part of a surface of said conductive film.

16. A contact hole formation method, comprising the steps of:
in forming on a conductive film an insulating interlayer including an insulating layer of a composition containing SiH, forming said insulating layer by applying a material film for said insulating layer, and then curing said material film with adjusting an H content in the composition of said material film to a predetermined value of not less than 15.4 atom %;
isotropically etching a surface layer of an upper insulating layer to form a recess having a moderately tapered wall surface on said surface layer; and
forming a contact hole which extends from said recess through said insulating interlayer to expose part of a surface of said conductive film.

17. A method of manufacturing a semiconductor device which has a semiconductor element on a semiconductor substrate, and a multilayered interconnection structure over said semiconductor element, said structure being electrically connected to said semiconductor element, said method comprising the steps of:
forming said multilayered interconnection structure into an interconnection structure of at least two layers in which a conductive film or a lower interconnection layer and an upper interconnection layer formed on an insulating interlayer are electrically connected through a contact hole formed in said insulating interlayer; and
forming at least one insulating layer to constitute said insulating interlayer, by applying a material film of a composition containing SiH, and then adjusting its SiH content so that a degassing amount from the insulating layer abruptly decreases upon a slight increase in the SiH content.

18. A method of manufacturing a semiconductor device which has a semiconductor element on a semiconductor substrate, and a multilayered interconnection structure over said semiconductor element, said structure being electrically connected to said semiconductor element, said method comprising the steps of:
forming said multilayered interconnection structure into an interconnection structure of at least two layers in which a conductive film or a lower interconnection layer and an upper interconnection layer formed on an insulating interlayer are electrically connected through a contact hole formed in said insulating interlayer; and
forming at least one insulating layer to constitute said insulating interlayer, by applying a material film of a composition containing SiH, and then curing said material film with adjusting an SiH content of said material film to a predetermined value of not less than 50% an SiH content immediately after applying.

19. A method of manufacturing a semiconductor device which has a semiconductor element on a semiconductor substrate, and a multilayered interconnection structure over said semiconductor element, said structure being electrically connected to said semiconductor element, said method comprising the steps of:
forming said multilayered interconnection structure into an interconnection structure of at least two layers in which a conductive film or a lower interconnection layer and an upper interconnection layer formed on an insulating interlayer are electrically connected through a contact hole formed in said insulating interlayer; and
forming at least one insulating layer to constitute said insulating interlayer, by applying a material film of a composition containing SiH, and then curing the material film with adjusting an H content in the composition of said material film to a predetermined value of not less than 15.4 atom %.
